(19) United States
(12) Patent Application Publication
(10) Pub. No.: US 2002/0179919 A1
(43) Pub. Date: Dec. 5, 2002

(54) Process for the production of an optoelectronic semiconductor component

(75) Inventors: Manfred Deisenhofer, Altenmuenster (DE); Ekkehard Messner, Augsburg (DE); Harald Strixner, Konigsbrunn (DE)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: PATENT-TREUHAND-GESELLSCHAFT FUR ELEKTRISCHE GLUHLAMPEN mbH, Munchen (DE)

(21) Appl. No.: 10/115,491

(22) Filed: Apr. 3, 2002

(30) Foreign Application Priority Data
Apr. 12, 2001 (DE) 10118630.4

(51) Int. Cl. H01L 33/00

(52) U.S. Cl. 257/99; 438/26

(57) ABSTRACT

A process for the production of an optoelectronic semiconductor component, and the component formed by the process. The component includes a chip which is provided with electrical terminals, and being fitted in a package which functionally consists of at least a base body and a top, both consisting of glass. The process includes the steps of:

a) producing and preparing two sintered glass preforms (glass bodies);

b) applying adhesive to the preform surfaces to be connected;

c) fixing the two preforms in a tool;

d) producing a mechanical connection of the two glass bodies to the electrical terminals.

Alternatively, further processes are described.

### TECHNICAL FIELD

The invention is based on a process for the production of an optoelectronic semiconductor component according to the preamble of claim 1. In particular, it concerns light-emitting diodes (LEDs).

### BACKGROUND ART

To date, the plastic packages used for LEDs have been injected directly onto the metal lead frame by using the injection molding method. In the plastic packages predominantly used to date, the radiation emitted by the LED causes damage (embrittlement, etc.) of the plastic, which can finally destroy the package or negate important properties of the package. The damage process is in this case exacerbated by the thermal load during continuous operation. This is particularly relevant to LEDs which emit shortwave radiation in the blue or ultraviolet spectral ranges.

EP-A 933 823 has already disclosed a process for the production of an optoelectronic semiconductor component, in which the thermal expansion coefficients of the individual constituent parts can differ only slightly (less than 15%). The package constituent parts consist of pressed glass or sintered glass and are adhesively bonded to one another. To that end, organic bonders (silicone or epoxy bonders) or inorganic bonders (water glass) are suitable. As an alternative, it is indicated to press-form prefabricated individual parts (glass preforms) and fuse them directly to one another.

Furthermore, U.S. Pat. No. 5,981,945 discloses an LED in which the constituent parts of the package are made of glass, and are connected by a solder or adhesion layer.

### DISCLOSURE OF THE INVENTION

It is an object of the present invention to provide processes for the production of an optoelectronic component, the component consisting of a chip which is provided with electrical terminals, and the chip being fitted in a package which functionally consists of at least a base body and a top, both consisting of glass, said package is resistant to both light and UV and, in particular, is also thermally stable and moisture-proof.

A semiconductor component is proposed whose package is made completely of glass. Glass does not suffer any relevant aging or damage due to visible or UV light. Moisture-resistant glasses which have a low transformation temperature are employed, for example glass containing lead borate, as described in U.S. Pat. No. 4,783,612.

The package consists of at least two parts, namely a base body and a top which is fastened on the base body. This two-part configuration is to be understood in the context of a functional division. Depending on the process, the package may also be embodied integrally. Both parts are made of glass, the two parts preferably being made of the same material. This is not, however, a necessary prerequisite. Also required are electrical terminals which can connect the chip to an electrical voltage source. These will also be referred to below, as a generalization, by the term lead frame. The variety of LED package forms which can be produced in this way ranges from radial LEDs to so-called top LEDs, as are described in the prior art mentioned in the introduction. The terminals may be made of the previously known materials such as copper, copper-clad wire or Ni—Fe alloys.

The glass package can be produced in various ways. These production methods can be divided into two groups: assembly techniques, in which at least two predefined glass parts of the package are joined together using auxiliaries, and injection or casting techniques, in which the package as a whole is sintered or cast together with the terminals in a mold. Assembly techniques are based on producing the shaped glass parts in a first step and preparing them for further processing. The shaped parts are preferably sintered preforms. A binder (bonder or glass solder) is then applied to the contact surfaces which are to be connected, after the shaped parts have been fixed in a tool (mold). Finally, the shaped glass parts, together with the terminals, are connected. In injection and casting techniques, a liquid glass compound or a glass powder plasticized by pressing auxiliaries is heated and introduced into a mold by injection or die casting. The electrical terminals are also fixed in the mold. The mold is cooled slowly following a defined temperature program.

A first process using an assembly technique involves the adhesive bonding of prefabricated glass parts, as is known in principle. In this case, the package may be assembled from glass parts, using a suitable organic or inorganic bonder, with the metal lead frame. The glass parts may have been produced e.g. as sintered glass parts or pressed glass parts.

Since the shaping of the glass bodies takes place separately from the assembly process, this assembly process does not entail any limitation in terms of the softening temperature of the glass. When an organic bonder is used, a large selection of suitable glasses is available, since the elastic behavior of the bonder also makes it possible to compensate for large differences in thermal expansion during operation. For example, this process works even if a glass having a thermal expansion coefficient of 5×10⁻⁶ K⁻¹ is connected to a metal having a thermal expansion coefficient of about 20×10⁻⁶ K⁻¹. The difference in the thermal expansion coefficients can hence be up to 80 percent, expressed in terms of the larger value.

Of the large number of organic bonders, silicones and epoxy resins, for example, are particularly well suited.

Suitable process steps are:

a) Producing the constituent parts (shaped glass parts) from sintered glass using methods which are known per se: Melting and fritting a glass. The frit may be produced by wet or dry fritting. Grinding the glass frit to form a glass powder of suitable particle size. Agglomerating the powder by adding an organic binder. Cold pressing the dried agglomerate to form a green body having the desired shape. Drying, expelling the organic binder and finally sintering the glass bodies in the furnace at approximately 100 to 200° C. above the transformation temperature of the glass.

b) Producing a connection of the constituent parts (shaped glass parts) to the terminals (lead frame) by means of an (in particular organic) bonder: A pneumatic dispenser may be used for accurate dosing of a bonder (e.g. silicone bonder). Applying the adhesive to the regions of the shaped glass parts which are to be adhesively bonded to the metal, or to the other shaped glass part. The most accurate possible dosing of the adhesive is important, so that no metal surfaces which are needed for connecting and fastening the LED become covered with bonder, although an untight adhesive bond due to insufficient bonder must also be avoided. For adhesive bonding, the base body and the top need to be fixed in a tool, positioned accurately in relation to the lead frame and have a slight application pressure applied to them (preferably corresponding to a weight corresponding to a mass of at least 2 g, in particular up to 20 g, in each case referring to a single package). Curing the silicone bonder over 10 minutes at temperatures above 100° C., in particular at about 200° C.

A second process using an assembly technique involves the soldering of glass parts. In this case, the glass parts are assembled with the metal lead frame using a suitable glass solder. The glass parts may again have been produced e.g. as sintered glass parts or alternatively as pressed glass parts.

Since the shaping of the glass bodies takes place separately from the assembly process, the latter does not entail any limitation in terms of the softening temperature of the glass. The expansion coefficient of the glass should not differ too greatly (≦factor 1.8 difference) from that of the metal which is used, in order to avoid the creation of excessive stresses. For example, a glass having a thermal expansion coefficient of from 10 to 13×10⁻⁶ (K⁻¹) is suitable. It is combined with a solder glass, whose thermal expansion coefficient is about from 14 to 17×10⁻⁶ (K⁻¹), and with a lead frame made of copper (having a thermal expansion coefficient of about 18×10⁻⁶ (K⁻¹)). A glass such as Schott 4210 is suitable for the shaped glass parts. A glass such as the phosphate glass from U.S. Pat. No. 5,965,469 is suitable as the solder glass.

The value of the expansion coefficient of the glass solder must lie between the values of the expansion coefficients of the glass which is used and of the metal. The solder must melt below the transformation temperature of the glass of the shaped parts, so that uncontrolled deformation of the glass parts does not take place.

Suitable process steps are as follows:

a) Producing the constituent parts (preforms) from sintered glass using methods which are known per se: Melting and fritting a glass. The frit may be produced by wet or dry fritting. Grinding the glass frit to form a glass powder of suitable particle size. Agglomerating the powder by adding an organic binder. Cold pressing the dried agglomerate to form a green body having the desired shape. Drying, expelling the organic binder and sealing by sintering the glass bodies in the furnace at approximately 100 to 200° C. above the transformation temperature of the glass.

b) Soldering: Mixing the powdered glass solder with an organic binder, until it has a paste-like consistency. Applying the glass solder paste to the regions of the preforms (shaped glass parts) which are to be adhesively bonded to the metal, or to the other glass part. Accurate dosing of the glass solder is important, so that no metal surfaces which are needed for connecting and fastening the LED become covered with solder, although untight soldering bond due to insufficient solder must also be avoided. A pneumatic dispenser may be used for accurate dosing of the glass solder paste. Drying, expelling the organic binder and sealing by sintering the solder applied to the sintered glass parts. For soldering, the two preforms (in particular an upper part and a lower part) then need to be fixed in a tool and positioned accurately in relation to the lead frame. The connection is produced by soldering together in a furnace under a protective gas at 100° C. to 300° C. above the transformation temperature of the solder, in which case a slight application pressure should be imparted to the parts (preferably corresponding to a weight of at least 10 g, in particular up to 20 g, mass per package).

A third process is based on a casting technique, and involves the pressure casting of liquid glass. In this case, the glass in the liquid state is injected directly around the metal lead frame. For this process, particularly inert materials, for example boron nitride, should be used both for the injection unit and for the contact surfaces of the mold into which the liquid glass is injected, in order to prevent reaction and adhesive bonding of the glass with the tools. Accurate temperature control in all the process steps is likewise important.

Upon heating to below the melting point of the metal, the glass must reach a viscosity which is low enough, advantageously in the range of from 0.5 to 2×10⁴ dpa.s, so that it can be injected in liquid form, and it should therefore have a transformation temperature which is as low as possible (≦400° C.). The expansion coefficient of the glass must be matched to that of the metal (the difference should correspond at the most to a factor 1.3) so as to ensure a durable glass/metal connection after the glass has solidified. The glass should be crystallization-resistant, otherwise there is a risk of crystallization during the injection process. In order to prevent reaction of the glass with the injection unit and the mold, and adhesive bonding due to this, the surfaces of the tools (injection unit, mold) which are in contact with the glass must consist of a material which does not react with the glass and to which the glass adheres only weakly. Hexagonal boron nitride (BN) has been found to be suitable for this. The contact surfaces of the tools may therefore consist of metal (for example molybdenum) coated with boron nitride or directly of solid hexagonal boron nitride.

Suitable process steps are as follows:

Producing a glass compound in the liquid state, for example by melting and fritting a glass. Preparing the glass compound by melting the frit in a heated injection unit. Injecting the glass compound into a separable mold with electrical terminals (in particular a lead frame) placed in it beforehand. Cooling and opening the mold (mold release) after the glass has solidified. The injection normally takes place under pressure.

For this process, the temperatures of the injection unit and of the mold should be separately controllable. Mold temperature regulation suited to the glass which is used is necessary so that the shaped body neither sticks to the mold (if the temperature is too high) nor tears owing to thermal shock if the cooling is too fast.

A fourth process using an assembly technique is based on sintering together glass moldings. In this case, the glass powder moldings together with the inserted lead frame are subjected to a sintering process, so that a firm connection of glass and metal is obtained. To assist the co-sintering, a bilateral pressure may advantageously be applied to the constituents to be assembled, so that pressure sintering takes place, in particular corresponding to a weight which is exerted by a mass of 20 to 50 g (referring to a single package). To carry out the sintering successfully, it is favorable for the moldings to be unsintered before the assembly process, or to be pre-sintered only slightly (corresponding to about 5 to 20% of the normal sintering time). For this process, it is necessary to select a glass, for example a phosphate glass similar to that described in U.S. Pat. No. 5,965,469, for which the sintering temperature lies below the melting temperature of the metal. The expansion coefficient of the glass must be matched (at most a factor of 1.3 difference) to that of the metal (usually copper in this case). It should therefore be at least 14×10⁻⁶ K⁻¹, so as to ensure a durable glass/metal connection after the glass has been sintered.

During the sintering process, it is recommendable to use a protective gas (in particular argon) in order to avoid corrosion of the metal lead frame. The metal tool used for positioning during the sintering process should be coated in order to prevent adhesion of the glass. To that end, a layer of hexagonal boron nitride on the contact faces has already been found to be sufficient.

Suitable process steps are:

a) Producing and preparing glass powder in the form of two moldings using methods which are known per se: Melting and fritting a glass. The frit may be produced by wet or dry fritting. Grinding the glass frit to form a glass powder of suitable particle size. Agglomerating the powder by adding an organic binder. Cold pressing the dried agglomerate to form a green body having the desired shape. Drying, debinding and briefly pre-sintering the shaped bodies using a suitable temperature program in the furnace.

b) Assembling by sintering on or pressure sintering: Placing the moldings and the metal lead frame (between the moldings) in a tool (separable mold), which permits accurate positioning of the shaped parts in relation to one another. Pre-sintering the shaped body formed thereby. Applying a bilateral pressure and finally sintering under a protective gas at 100° C. to 200° C. above the transformation temperature of the glass. To assist the sintering process, the bilateral pressure is necessary so that the shaped glass parts are sintered together across the gap (typically 0.13 mm) due to the lead frame. Removing from the tool after cooling and opening the mold.

A fifth process involves the injection molding technique. In this case, the glass powder is processed by using an organic plasticizer, in a similar way to the injection molding of technical ceramics, see “Overview of Powder Injection Molding” by P. J. Vervoort et al., in: Advanced Performance Materials 3, pp. 121-151 (1996). The plasticized glass powder compound is injected directly onto or around the metal lead frame. A debinding process step is then carried out, before the “green body” obtained in this way is sealed by sintering. During the sintering process, it is recommendable to use a protective gas (in particular argon) in order to avoid corrosion of the metal.

For this process, it is necessary to select a glass whose sintering temperature lies below the melting temperature of the metal (preferably <600° C.) and above the debinding temperature of the plasticizer (preferably >400° C.). The expansion coefficient of the glass must furthermore be matched to that of the metal (maximum difference corresponding to a factor 1.3); it should preferably be selected as being ≧14×10⁻⁵ K, so as to ensure a durable moisture-proof glass/metal connection after sintering. The glass should be moisture-resistant; its hydrolytic stability should preferably correspond to at least class 3.

Suitable process steps are:

Producing a glass powder by melting and fritting a glass (using methods which are known per se): The frit may be produced by wet or dry fritting. Grinding the glass frit to form a glass powder of suitable particle size. A median particle diameter d₅₀ of d₅₀<10 μm is preferred. Plasticizing the glass powder in a kneader. In this case, a suitable quantity of glass powder (for example 80% glass) is blended as homogeneously as possible with an organic binder or plasticizer which is suitable for the injection molding (remainder: for example Siliplast HO from the company Zschimmer & Schwarz). Introducing the plasticized glass powder into a heated injection unit (at 140 to 200° C.; 160° C. is typical) Injecting this compound under pressure (at least 5 MPa, in particular approximately 20-30 MPa) into a separable mold with electrical terminals (in particular a lead frame) placed in it beforehand. Cooling, to obtain a rigid green body. Opening the mold and extracting the green body (mold release) after the green body has solidified. For this process, the temperatures of the injection unit and of the mold should be separately controllable. The thermal or chemical debinding of the green body then takes place. This is followed by sealing by sintering, or final sintering, under a protective gas in a furnace at 100° to 200° above the transformation temperature of the glass, corresponding to an absolute temperature of about 400 to 600° C.

### BRIEF DESCRIPTION OF THE DRAWINGS

The invention will be explained in more detail with reference to several exemplary embodiments.

FIG. 1 shows a semiconductor component, in section;

FIG. 2 shows the same semiconductor component in plan view;

FIG. 3 shows another semiconductor component in section.

### BEST MODE FOR CARRYING OUT THE INVENTION

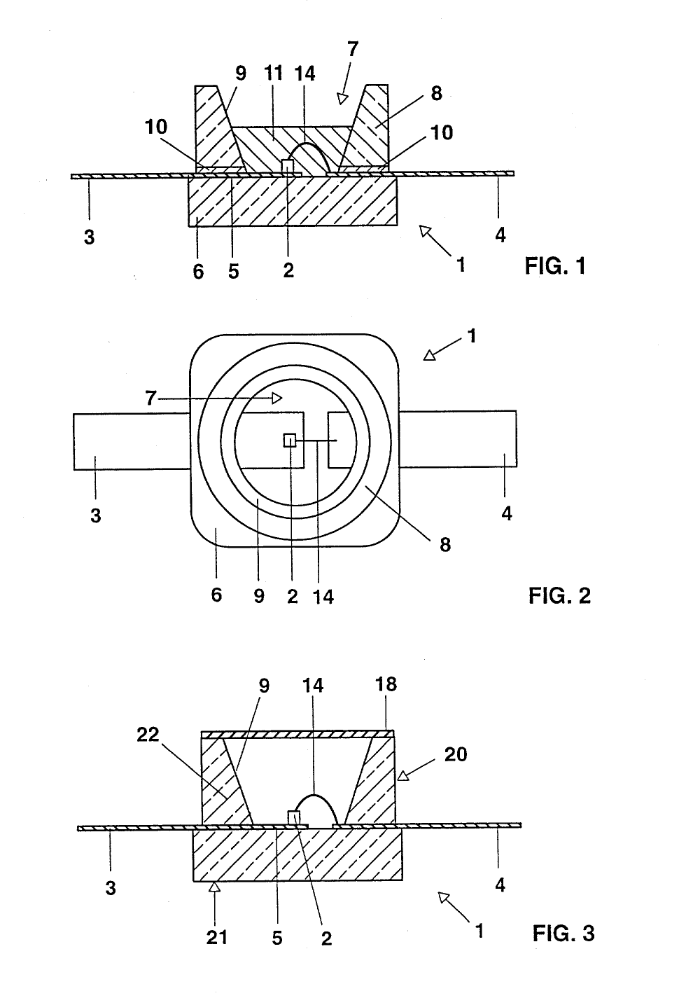

An optoelectronic semiconductor component 1 is shown in FIGS. 1 and 2. The center piece is the chip 2, which emits primarily UV radiation and is connected to electrical terminals 3, 4, which are designed as lead frame parts. One of the parts 4 is joined to the chip via a bonding wire 14. The chip 2 sits directly on the wide terminal 3, which is arranged on the surface 5 (or alternatively in a suitable recess) of a rectangular base body 6 made of glass. A ring-shaped top 8, which surrounds the chip and leaves a recess 7 exposed in its interior, is fitted on the base body 6. The inner oblique wall of the top 8 is formed as a reflector 9. The top 8 is connected to the base body 6 and to the lead frames 3, 4 by a bonder or a solder glass 10. The top 8 is likewise made of a glass. The recess 7 inside the reflector 9 is, as known per se, filled with a casting resin 11, which optionally comprises a wavelength-converting luminescent material.

FIG. 3 shows a semiconductor component which is in principle similar to the one in FIG. 1 (the same reference numbers denote the same parts). In contrast thereto, however, it is made by using an injection or casting technique. The package 20, consisting of the base body 21 and the top 22, is therefore formed integrally from an injected or cast glass body. A cover disk 18 is also fastened on the top 22.

Example of an embodiment of FIG. 1

An embodiment with reference to FIG. 1 is a semiconductor component using a chip connected to a leadframe of Cu having a silver layer on it. The bonding wire is of gold. The glass bodies for the base body 6 and the top 8 are made of bismuth containing borosilicate glass, which is Pb-free (type CERDEC 10 179). The two glass bodies 6, 8 are mechanically connected by means of an adhesive which is a one-component silicone rubber (caoutchuc bonder) of the type Semicosil 988 1/K.A pneumatic dispenser is used for dosing of the Semicosil rubber.

The above is by way of exemplification and not intended to be limitative of the invention.

What is claimed is:

1. A process for the production of an optoelectronic semiconductor component, the component consisting of a chip which is provided with electrical terminals, and the chip being fitted in a package which functionally consists of at least a base body and a top, both consisting of glass, wherein the following process steps are employed:
a) producing and preparing two sintered glass preforms (glass bodies);
b) applying adhesive to the preform surfaces to be connected;
c) fixing the two preforms in a tool;
d) producing a mechanical connection of the two glass bodies to the electrical terminals.

2. The process as claimed in claim 1, wherein a pneumatic dispenser is used for accurate dosing of the adhesive in process step b).

3. The process as claimed in claim 1, wherein a slight application pressure (preferably corresponding to a weight of at least 2 g mass) is used in process step d).

4. The process as claimed in claim 1, wherein a step e) is carried out as an additional process step:
e) curing the bonder, in particular at a temperature above 100° C.

5. A process for the production of an optoelectronic semiconductor component, the component consisting of a chip which is provided with electrical terminals, and the chip being fitted in a package which functionally consists of at least a base body and a top, both consisting of glass, wherein the following process steps are employed:
a) producing and preparing two sintered glass preforms (glass bodies);
b) mixing powdered glass solder with an organic binder to form a paste;
c) applying the paste to the preform surfaces to be connected;
d) fixing the two preforms in a tool;
e) producing a connection of the two glass bodies to the electrical terminals.

6. The process as claimed in claim 5, wherein a pneumatic dispenser is used for accurate dosing of the paste in process step c).

7. The process as claimed in claim 5, wherein a slight application pressure (preferably corresponding to a weight of from at least 10 to 20 g mass) is used in process step e).

8. The process as claimed in claim 5, wherein a temperature which is from 100 to 300° C. above the transformation temperature of the glass solder is employed in process step e).

9. The process as claimed in claim 5, wherein the thermal expansion coefficients of the glass and of the metal terminals differ at most by the factor 1.8, the thermal expansion coefficient of the glass solder lying between those of the glass and of the terminals.

10. A process for the production of an optoelectronic semiconductor component, the component consisting of a chip which is provided with electrical terminals, and the chip being fitted in a package which functionally consists of at least a base body and a top, both consisting of glass, wherein the following process steps are employed:
a) producing a glass compound in the liquid state and preparing the glass compound in a heated injection unit;
b) injecting the glass compound from the injection unit into a separable mold, in which the electrical terminals are also fixed;
c) cooling and opening the mold.

11. The process as claimed in claim 10, wherein at least the contact surface of the mold, and optionally that of the injection unit, is lined with an inert material, in particular with boron nitride.

12. The process as claimed in claim 10, wherein the thermal expansion coefficients of the glass and of the terminals differ at most by the factor 1.3.

13. A process for the production of an optoelectronic semiconductor component, the component consisting of a chip which is provided with electrical terminals, and the chip being fitted in a package which functionally consists of at least a base body and a top, both consisting of glass, wherein the following process steps are employed:
a) preparing glass powder in the form of two preforms, which are intended to form the base body and the top;
b) introducing the preforms into a separable mold, in which the electrical terminals are also fixed between the two preforms;
c) pre-sintering the shaped body formed in this way;
d) finally sintering the shaped body;
e) cooling and opening the mold.

14. The process as claimed in claim 13, wherein step d) is carried out under pressure (in particular corresponding to a weight of at least 20 to 50 g mass), in particular under bilateral pressure.

15. The process as claimed in claim 13, wherein step d) is carried out at a temperature of from 100 to 200° C. above the transformation temperature of the glass.

16. The process as claimed in claim 13, wherein at least the contact surfaces of the mold consist of an inert material, in particular boron nitride.

17. A process for the production of an optoelectronic semiconductor component, the component consisting of a chip which is provided with electrical terminals, and the chip being fitted in a package which functionally consists of at least a base body and a top, both consisting of glass, wherein the following process steps are employed:
a) producing a glass powder;
b) adding an organic plasticizer to the glass powder and introducing the plasticized compound into a heated injection unit;
c) injecting the compound from the injection unit into a separable, separately heatable mold, in which the electrical terminals are also fixed;
d) cooling, by means of which a green body is obtained;
e) opening the mold;
f) debinding the green body;
g) sealing the green body by sintering.

18. The process as claimed in claim 17, wherein step g) is carried out at a temperature below the melting point of the material of the metal terminals and above the debinding temperature of the plasticizer.

19. The process as claimed in claim 18, wherein step g) is carried out at a temperature of from 100 to 200° C. above the transformation temperature of the glass.

20. The process as claimed in claim 17, wherein a protective gas atmosphere is applied during step g).

21. The process as claimed in claim 17, wherein the thermal expansion coefficients of the glass and of the terminals differ at most by the factor 1.3.

22. The process as claimed in claim 17, wherein the glass is moisture-resistant.

23. In an optoelectronic semiconductor component comprising a light emitting semiconductor component encased in a moisture resistant enclosure the improvement wherein the moisture resistant enclosure is made of glass and comprises:
a base formed of glass;
a top formed of glass; and
electrical terminals passing through said enclosure and connecting to the light emitting semiconductor enclosure whereby the light emitting semiconductor component can be connected to an outside electrical voltage source.

24. The optoelectronic semiconductor component of claim 23 wherein said base and said top are separate parts which are adhered together.

25. The optoelectronic semiconductor component of claim 24 wherein the light emitting semiconductor component is a U-V emitting or visible light emitting LED.

26. The optoelectronic semiconductor component of claim 23 wherein said base and said top are formed as a unitary structure.
